(19) United States
(12) Patent Application Publication
(10) Pub. No.: US 2023/0352513 A1
(43) Pub. Date: Nov. 2, 2023

(54) ELECTRICAL CONNECTION AND ITS METHOD OF FABRICATION

(71) Applicant: STMicroelectronics (Crolles 2) SAS, Crolles (FR)

(72) Inventors: Alain INARD, Saint Nazaire Les Eymes (FR); Emmanuel JOSSE, Saint Nazaire Les Eymes (FR)

(73) Assignee: STMicroelectronics (Crolles 2) SAS, Crolles (FR)

(21) Appl. No.: 18/303,409

(22) Filed: Apr. 19, 2023

(30) Foreign Application Priority Data
May 2, 2022 (FR) 2204130

(51) Int. Cl. H01L 27/146

(52) U.S. Cl. CPC H01L 27/14636; H01L 27/14634; H01L 27/1469; H01L 24/29

(57) ABSTRACT

The present description concerns a manufacturing method comprising the following steps: providing a silicon substrate having a via penetrating into the substrate from its front surface and comprising a silicon conductive core and a silicon oxide insulating sheath; etching the substrate from its rear surface, selectively over the sheath so that a portion of said at least one via protrudes from the rear surface; depositing a silicon oxide insulating layer on the rear surface; polishing the insulating layer to expose the core while leaving in place a portion of the thickness of the insulating layer; and forming a conductive electrode in contact with the core.

### CROSS-REFERENCE TO RELATED APPLICATION(S)

This application claims the priority benefit of French patent application number N°22/04130 filed on May 2, 2022, entitled “Connexion électrique et son procédé de fabrication” which is hereby incorporated by reference to the maximum extent allowable by law.

### BACKGROUND

### Technical Field

The present disclosure generally concerns electronic circuits and, more specifically, electrical connections in electronic circuits. The present disclosure also concerns an electronic circuit manufacturing method and, more particularly, an electrical connection in such a circuit.

### Description of the Related Art

Electronic circuits or devices comprising a silicon substrate having a first surface, called front surface, coated with an interconnect structure currently called back end of line (BEOL) interconnect structure, and a second surface, called rear surface, opposite and parallel to the first surface, are known.

When a conductive electrode is provided on the rear surface side of the substrate, an electronic connection electrically connects the electrode to the interconnect structure coating the front surface.

However, these known electrical connections and their manufacturing methods have defects.

### BRIEF SUMMARY

There is a need to overcome all or part of the disadvantages of known electronic devices comprising an electrical connection such as described hereabove and of known methods of manufacturing these electronic circuits.

For example, these is a need to overcome all or part of the disadvantages of an electrical connection such as previously described comprised by these known electronic devices, and of known methods of manufacturing such an electrical connection.

An embodiment overcomes all or part of the disadvantages of known electronic devices comprising an electrical connection such as described hereabove and of known methods of manufacturing these electronic devices.

For example, an embodiment overcomes all or part of the disadvantages of an electrical connection such as previously described comprised by these known electronic devices, and of known methods of manufacturing such an electrical connection.

An embodiment provides a manufacturing method comprising the following steps:
providing a silicon substrate having a front surface coated with an interconnect structure, a rear surface opposite to the front surface, at least one via vertically penetrating into the substrate from the front surface across a portion of the substrate thickness, said at least one via comprising a silicon conductive core and a silicon oxide insulating sheath capable of comprising silicon nitride, the sheath covering the core and electrically insulating it from the substrate;
etching, from the rear surface, the substrate selectively over the sheath so that a portion of said at least one via protrudes from the rear surface;
depositing a silicon oxide insulating layer capable of comprising silicon nitride on the side of the rear surface across a thickness greater than a height of the portion protruding of said at least one via;
performing a chemical-mechanical polishing of the insulating layer to expose the conductive core of said at least one via while leaving in place a portion of the thickness of the insulating layer on the rear surface; and
forming a conductive electrode on the side of the rear surface and in contact with the core of said at least one via.

According to an embodiment, the step of forming of the electrode comprises the deposition of a conductive layer on the insulating layer and in contact with the core of said at least one via, and a step of removal of a portion of the conductive layer while leaving in place said electrode.

According to an embodiment, the insulating layer is deposited on top of and in contact with the rear surface of the substrate and the protruding portion of said at least one via.

According to an embodiment, the method further comprises, between the polishing step and the step of forming of the electrode, a step of etching of a portion of the core of said at least one via, the etching being implemented on the side of the rear surface and being selective over the sheath and over the insulating layer.

According to an embodiment, the method further comprises, after the step of forming of the electrode, a step of forming of a quantum film resting on the insulating layer and the electrode.

According to an embodiment, the method further comprises:
a step of provision of an additional silicon substrate having a front surface coated with an additional interconnect structure and a rear surface opposite to the front surface of the additional substrate and intended to receive light; and
a step of assembly of the interconnect structure on the additional interconnect structure.

According to an embodiment, the quantum film is configured to convert infrared light into electron-hole pairs and the electrode is made of a material transparent to infrared light, for example, made of zinc oxide and/or of indium-tin oxide.

According to an embodiment, the sheath of said at least one via is in contact with the core of said at least one via.

An embodiment provides a device comprising:
a silicon semiconductor substrate comprising a front surface and a rear surface opposite to the front surface;
an interconnect structure coating the front surface;
a silicon oxide insulating layer capable of comprising silicon nitride, the insulating layer resting on the rear surface;
at least one via comprising a silicon conductive core laterally covered with a silicon oxide insulating sheath capable of comprising silicon nitride, said at least one via crossing the substrate from its front surface, at least the sheath of said at least one via crossing the insulating layer and being flush with a first surface of the insulating layer opposite to a second surface of the insulating layer facing the substrate; and
a conductive electrode resting on top of and in contact with the conductive core of said at least one via, on the rear surface of the substrate.

According to an embodiment, the device further comprises a quantum well resting on the insulating layer and the electrode.

According to an embodiment, the device further comprises an additional silicon substrate and an additional interconnect structure resting on a front surface of the additional substrate, the interconnect structure being assembled on the additional interconnect structure and the additional substrate comprising a rear surface opposite to its front surface and intended to receive light.

According to an embodiment, the quantum film is configured to convert infrared light into electron-hole pairs and the electrode is made of a material transparent to infrared light, for example, made of zinc oxide and/or of indium-tin oxide.

According to an embodiment, the sheath of said at least one via is in contact with the core of said at least one via.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1 is a cross-section view illustrating an example of an electronic device comprising an electrical connection;

FIGS. 2A, 2B, 2C illustrate, in three cross-section views, steps of an example of a method of manufacturing an electrical connection of the device of FIG. 1;

FIGS. 3A, 3B, 3C, 3D, 3E illustrate, in five cross-section views, steps of an embodiment of a method of manufacturing an electrical connection of the device of FIG. 1;

FIG. 4 shows, in a cross-section view, a step of a method of manufacturing the device of FIG. 1 according to an embodiment; and

FIG. 5 shows in a cross-section view another step of a method of manufacturing the device of FIG. 1 according to an embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the various known circuits comprise an electrical connection electrically connecting a conductive electrode arranged on the side of the rear surface of the silicon substrate of the circuit and a back-end-of-line interconnect structure resting on the front surface of the substrate have not been detailed, the described embodiments and variants being compatible with these known circuits.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front,” “rear,” “top,” “bottom,” “left,” “right,” etc., or relative positions, such as terms “above,” “under,” “upper,” “lower,” etc., or to terms qualifying directions, such as terms “horizontal,” “vertical,” etc., it is referred to the orientation of the drawings.

Unless specified otherwise, the expressions “around,” “approximately,” “substantially” and “in the order of” signify within 10%, and preferably within 5%.

FIG. 1 is a cross-section view illustrating an example of an electronic device 1 comprising an electrical connection such as previously described.

Device 1 comprises a first chip IR.

Chip IR comprises a silicon substrate SUB2 having a front surface 100 and a rear surface 102 opposite to the front surface 100.

The front surface 100 is coated with a back-end-of-line interconnect structure BEOL2. Although this is not detailed in FIG. 1, interconnect structure BEOL2 comprises portions of electrically-conductive layers embedded in electrically-insulating layers, and vias coupling the portions of electrically-conductive layers together and/or to components, for example, transistors (not shown), formed inside and on top of substrate SUB2 on the side of its surface 100 and/or to electrical connection pads (not shown) formed on a side of a first surface of structure BEOL2 opposite to a second surface of structure BEOL2, the electrical connection pads being arranged in front and on the side of surface 100 of substrate SUB2.

Chip IR comprises an electrically-conductive electrode 104 arranged on the side of surface 102 of substrate SUB2. For example, electrode 104 rests on surface 102.

In this example, chip 104 comprises a quantum film QF covering surface 102 of substrate SUB2, the film being in contact with electrode 104. Although this is not shown in FIG. 1, an insulating layer is arranged between film QF and substrate SUB2 to electrically insulate them from each other.

Film QF is configured to convert light received in a given wavelength range into electron-hole pairs. For example, film QF is configured to convert infrared light into electron-hole pairs, that is, light having wavelengths for example in the range from 780 nm to 1.5 µm.

Chip IR is for example an infrared image sensor configured to receive light 106 from its front surface.

In the example of FIG. 1, device 1 further comprises a second chip RGB.

Chip RGB comprises a silicon substrate SUB1 having a front surface 108 and a rear surface 110 opposite to front surface 108.

Front surface 108 is coated with a back-end-of-line interconnect structure BEOL1 (in the orientation of FIG. 1, substrate SUB1 rests on structure BEOL1). Although this is not detailed in FIG. 1, interconnect structure BEOL1 comprises, like interconnect structure BEOL2, portions of electrically-conductive layers embedded in electrically-insulating layers, and vias coupling the portions of electrically-conductive layers together and/or to components, for example, transistors (not shown), formed inside and on top of substrate SUB1 on the side of its surface 108, and/or to electrical connection pads (not shown) formed on the side of a first surface of structure BEOL1 opposite to a second surface of structure BEOL1, the electrical connection pads being arranged in front and on the side of surface 108 of substrate SUB1.

Chip RGB is for example a visible light sensor configured to receive light 106 from its rear surface 110. For example, chip RGB is configured to convert visible light into electron-hole pairs, for example light having wavelengths in the range from 400 nm to 650 nm.

Although this is not shown in FIG. 1, one or a plurality of anti-reflection layers and/or filers and/or lenses may rest on surface 110 of substrate SUB1.

In the example of FIG. 1, chip RGB is mounted on, or assembled with, chip IR. More particularly, in this example, the front surface 100 of substrate SUB2 faces the front surface 108 of substrate SUB1. For example, structure BEOL1 is mounted on, or assembled with, structure BEOL2, for example to ensure an electrical connection between the IR and RGB chips. For example, structure BEOL2 may comprise, on the side of its surface facing structure BEOL1, one or a plurality of antireflection layers and/or filters, for example configured to only let through infrared light. For example, the surface of structure BEOL1 facing structure BEOL2 is in contact with the surface of structure BEOL2 facing structure BEOL1. For example, structure BEOL2 may comprise, on the side of its surface facing structure BEOL1, a bonding layer, for example, made of silicon oxide, in contact with structure BEOL1, and/or structure BEOL1 may comprise, on the side of its surface facing structure BEOL2, a bonding layer, for example, made of silicon oxide, in contact with structure BEOL2.

In the example of FIG. 1, the light 106 received by device 1 on the rear surface 110 of substrate SUB1 comprises wavelengths in the visible range and wavelengths in infrared. Light 106 first reaches substrate SUB1 where the visible light is converted into electron-hole pairs. Part of light 106 which is not converted into electron-hole pairs in substrate SUB1 and which comprises wavelengths in infrared then crosses substrate SUB1, structures BEOL1 and BEOL2, and substrate SUB2 before reaching film QF where the infrared light is converted into electron-hole pairs.

Chip IR comprises an electrical connection 112 crossing substrate SUB2 from its surface 100 all the way to electrode 104. Connection 112 enables to electrically connect electrode 104 to structure BEOL2.

Although this is not illustrated in FIG. 1, chip IR may comprise a plurality of connections 112, for example each connected to a corresponding electrode 104.

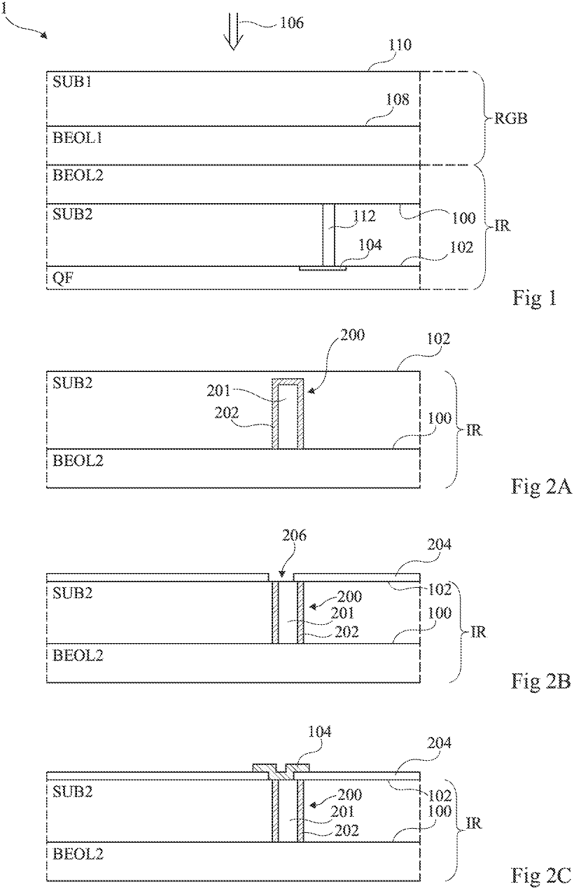

A problem of device 1, and more particularly of connection 112, is to ensure the electrical connection between electrode 104 and connection 112, while ensuring for electrode 104 and connection 112 to be electrically insulated from substrate SUB2, for example as appears from the example of manufacturing method illustrated in FIGS. 2A-2C.

FIGS. 2A, 2B, and 2C illustrate, in three cross-section views, steps of an example of a method of manufacturing the electrical connection 112 of the device 1 of FIG. 1.

At a step illustrated in FIG. 2A, a via 200 has been formed in substrate SUB2.

Via 200 penetrates into substrate SUB2 from its front surface 100. Via 200 penetrates into substrate SUB2 across a portion only of its thickness. In other words, via 200 does not cross substrate SUB2. Via 200 penetrates vertically into substrate SUB2, that is, in a direction orthogonal or transverse to the plane of surfaces 100 and 102 of substrate SUB2.

Via 200 is intended to form the electrical connection 112 of chip IR (FIG. 1). Via 200 comprises a core 201 and a sheath 202. Core 201 is electrically conductive.

Sheath 202 is electrically insulating. Sheath 202 covers core 201 and electrically insulates it from substrate SUB2, that is, from the silicon of substrate SUB2. For example, sheath 202 entirely covers the vertical (or lateral) walls of core 201, and entirely covers an end of core 201 opposite to surface 100, that is, the end of core 201 arranged on the side of surface 102. Thus, no portion of core 201 is in contact with substrate SUB2. Preferably, sheath 202 is in contact with core 201, for example, with all the lateral walls of core 201 and the end of core 201 most distant from surface 100. More preferably, the sheath comprises two main surfaces substantially parallel to each other, a first main surface of sheath 202 facing core 201 and being entirely in contact with core 201, and a second main surface of sheath 202 facing substrate SUB2 and being entirely in contact with substrate SUB2. In other words, sheath 202 is interposed between substrate SUB2 and core 201, with which it is in contact.

As an example, via 200 is formed by etching a trench in substrate SUB2 from surface 100 of the substrate and across a portion only of the thickness of substrate SUB2, by forming sheath 202 on the walls and the bottom of the trench, and then filling the trench with an electrically-conductive material forming the core 201 of via 200.

Although this is not illustrated in FIG. 2A, during the step of forming of via 200, surface 102 of substrate SUB2 may rest on top of and in contact with a handle, that is, a support layer.

Further, at the step of FIG. 2A, structure BEOL2 has been formed on surface 100 of substrate SUB2, the forming of such a structure BEOL2, for example by successive steps of deposition and of etching of conductive and insulating layers, being within the abilities of those skilled in the art.

At a next step illustrated in FIG. 2B, substrate SUB2 has been thinned, for example, by chemical-mechanical polishing, from its rear surface 102, to expose the core 201 of via 200, that is, to have removed the portion of sheath 202 that used to cover the end of core 201 on the rear surface 102 of substrate SUB2. Thus, via 200 is flush with the rear surface 102 of substrate SUB2.

Although this is not illustrated in FIG. 2A, when at the step of FIG. 2A, substrate SUB2 rests on a handle on the side of its surface 102, this handle is removed prior to the step of thinning of substrate SUB2 or during the thinning step.

The step of thinning of substrate SUB2 is followed by a step of forming of an insulating layer 204 on top of and in contact with surface 102 of substrate SUB2. Layer 204 is formed over the entire plate, that is, it entirely covers surface 102 and the portion of via 200 flush with surface 102. An opening 206 has then been formed through layer 204, to expose the portion of via 200 flush with surface 102.

The forming of opening 206 is implemented by forming an etch mask (not shown in FIG. 2B) on layer 204, the mask comprising a through opening at the location where opening 206 is desired to be formed. However, as well known by those skilled in the art, the alignment of the etch mask with via 200 is complex to implement and, due to a misalignment, the opening 206 formed due to the etch mask may then emerge not only onto via 200, but also onto substrate SUB2 as illustrated in FIG. 2B.

As a result, at a next step illustrated by FIG. 2C, the electrode 104 formed in opening 206 to be in contact with the core 201 of via 200 forming connection 112 (FIG. 1) is also in contact with substrate SUB2. Now, the contact of electrode 104 with substrate SUB2 raises an issue, since the contact of the electrode 104 and substrate SUB2 are then not electrically insulated from each other.

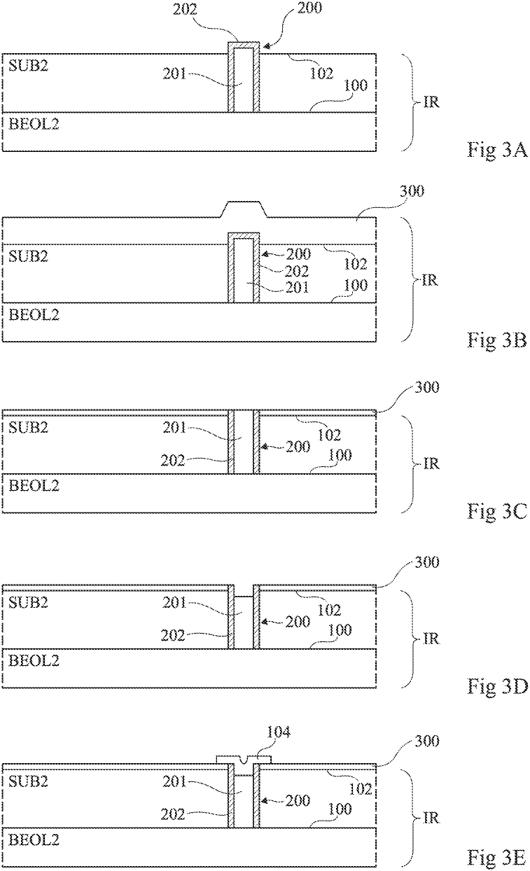

FIGS. 3A, 3B, 3C, 3D, and 3E illustrate, in five cross-section views, steps of an embodiment of a method of manufacturing an electrical connection 112 of the device of FIG. 1.

FIG. 3A illustrates a step of this implementation mode of a manufacturing method.

In the described embodiments, for example, the embodiment illustrated in FIG. 3A, the conductive core 201 of via 200 is made of silicon, for example, of doped polysilicon, and the insulating sheath 202 of via 200 is made of silicon oxide and may comprise silicon nitride. For example, sheath 202 may comprise any stoichiometry of silicon, nitrogen, and oxygen. For example, sheath 202 comprises a silicon oxide layer and may comprise a silicon nitride layer. For example, sheath 202 comprises a thermal silicon oxide layer formed from the silicon of substrate SUB2 coating the walls and the bottom of the trench having via 200 formed therein, and/or a deposited silicon oxide layer covering the walls and the bottom of the trench and may comprise a silicon nitride layer covering the walls and the bottom of the trench. Preferably, sheath 202 only comprises silicon oxide.

FIG. 3A illustrates chip IR at a step following the step described in relation with FIG. 2A.

At the step of FIG. 3A, substrate SUB2 has been etched from its surface 102, selectively over the sheath 201 of via 200. In other words, a portion of the thickness of substrate SUB2 has been removed from the side of surface 102, by etching the silicon of substrate SUB2 selectively over the silicon oxide of sheath 202. This etching of the silicon of substrate SUB2 may also be selective over the silicon nitride, for example, when sheath 202 comprises some. However, when sheath 202 comprises a silicon nitride layer and a silicon oxide layer separating the silicon nitride layer from substrate SUB2, the etching of the silicon of substrate SUB2 cannot be selective over the silicon nitride.

Although this is not illustrated in FIG. 2A, when at the step of FIG. 2A, substrate SUB2 rests on a handle on the side of its surface 102, this handle is removed prior to or simultaneously with the step of selective etching of substrate SUB2. Further, although this is not illustrated in FIG. 3A, substrate SUB2 may rest on a handle on the side of its surface 100 on implementation of the step of selective etching of substrate SUB2.

The etching is performed to expose a portion of via 200, and more exactly, so that a portion of via 200 protrudes from surface 102 of substrate SUB2, or, in other words, projects above surface 102. For example, the portion of via 200 protruding from surface 102 comprises a portion of core 201 and a portion of the sheath 202 covering core 201. For example, the thickness of the silicon removed during the etching is greater than the thickness of a portion of substrate SUB2 extending from via 200 to surface 102 before the etching. For example, the height of the protruding portion of via 200, measured from surface 102 of substrate SUB2, is greater than or equal to the height of sheath 202.

Due to the fact that the etching of substrate SUB2 is selective over sheath 202, for the entire portion of via 200 protruding from surface 102, sheath 202 covers core 201.

At a next step illustrated in FIG. 3B, an insulating layer 300 has been deposited on the side of rear surface 102 of substrate SUB2.

Insulating layer 300 is made of silicon oxide and may comprise silicon nitride. For example, sheath 202 may comprise any stoichiometry of silicon, nitrogen, and oxygen. For example, layer 300 may comprise a stack of silicon oxide layers and of silicon nitride layers. Preferably, layer 300 only comprises silicon.

Insulating layer 300 is for example formed on top of and in contact with surface 102 of substrate SUB2 and on top of and in contact with the portion of via 200 protruding from surface 102.

Insulating layer 300 is for example formed by one or a plurality of conformal deposition steps. The insulating layer is formed over the entire plate, so that it entirely covers surface 102 of substrate SUB2 and the portion of via 200 protruding from this surface 102.

The deposited layer 300 has a thickness greater than the height of the portion of via 200 protruding from surface 102. Thus, the entire surface of layer 300 which does not face surface 102, that is, the upper surface of layer 300 in the orientation of FIG. 3B, is more distant from surface 102 than the end of via 200 which protrudes from surface 102.

FIG. 3C illustrates chip IR at a step following the step described in relation with FIG. 3B.

At this next step, a chemical mechanical polishing (CMP) of layer 300 is performed. The CMP step is carried out until the core 201 of the via is exposed, but in such a way as to leave in place a portion of the thickness of layer 300 on the rear surface 102 of substrate SUB2, that is, so that, all around via 200, surface 102 of substrate SUB2 is entirely covered with the portion of insulating layer 300 left in place. In other words, only a portion of the thickness of layer 300 is removed during the CMP step and the removed thickness is sufficiently large for the CMP step to expose the core 201 of via 200.

The CMP step is not selective, conversely to the etch step described in relation with FIG. 3A. Thus, during this CMP step, the portion of sheath 202 which used to cover the top (in the orientation of FIG. 3C) is also removed, which enables to expose core 201. Due to the fact that the CMP step is not selective, a portion of core 201 may also be removed during this step.

As illustrated in FIG. 3C, at the end of the CMP step, the end of via 200 which is arranged on the side opposite to surface 100, that is, the end of the via which is arranged on the side of surface 102, is flush with surface 102. In other words, after the CMP step, the surface of chip IR which is exposed on the side of surface 102 of substrate SUB2 is planar.

As an example, the portion of layer 300 which is left in place at the end of the CMP step has a thickness in the range from 100 to 300 nm.

FIG. 3D illustrates chip IR at a step following the step described in relation with FIG. 3C. The step described in relation with FIG. 3D is optional and may be omitted.

The step of FIG. 3D is a step of etching of a portion of the core 201 of via 200. This etching is implemented on the rear surface side and is selective over sheath 202 and over insulating layer 300. In other words, the selectivity of the etching of FIG. 3D is similar or identical to that of FIG. 3A, so that only the silicon of core 201 is etched, the material(s) of the sheath and the material(s) of layer 300 being left in place.

As a result, an exposed surface of core 201 is then recessed with respect to the exposed surface of layer 300. Further, substrate SUB2 is not exposed by this etching due to the fact that layer 300 and sheath 200 are left in place. As an example, the advantage of having the exposed surface of core 201 recessed with respect to the exposed surface of layer 300 is to have a topology on which to align in order to define electrode 104. As an example, the distance between the exposed surface of layer 300 and the exposed surface of core 201 may be in the range from a few nanometers to a few hundreds of nanometers. For example, this distance may reach up to approximately half the thickness that substrate SUB2 has at the end of FIG. 3A.

FIG. 3E illustrates chip IR at a step following the step described in relation with FIG. 3D although, in an alternative embodiment where the step of FIG. 3D is omitted, the steps which will be described in relation with FIG. 3E are implemented from the chip IR obtained at the end of the steps of FIG. 3C.

More particularly, FIG. 3E illustrates a step of forming of electrode 104 on the side of surface 102 and in contact with core 201.

According to an embodiment, the forming of electrode 104 comprises the deposition of an electrically-conductive layer on top of and in contact with layer 300 and core 201, the conductive layer being also formed on top of and in contact with the portions of sheath 202 which are exposed at the end of the step of FIG. 3C or of the step of FIG. 3D when the latter is implemented. As an example, the conductive layer is deposited on the side of surface 102 of substrate SUB2, for example, conformally, and preferably over the entire plate.

According to an embodiment, the forming of electrode 104 further comprises a step of removal, down to layer 300, of a portion of the conductive layer resting on this layer 300 while leaving in place electrode 104. In other words, electrode 104 is defined by etching in the conductive layer.

Electrode 104 entirely covers the top of core 201 on the side of surface 102, and in contact with the entire top of core 201 on the side of surface 102. Electrode 104 may further extend over part of layer 300, around via 200.

At the end of the step of FIG. 3E, the core 201 of via 200, that is, the portion of the core 201 of via 200 which has not been removed during the previous steps, forms, or is, an electrical connection 112 extending from the surface 100 of substrate SUB2 to electrode 104. Although this is not illustrated in FIG. 3E, on the side of surface 100, the core 201 of via 200, that is, connection 112, is electrically connected to structure BEOL2, for example, to a conductive element, conductive via, or conductive layer portion, of this structure BEOL2.

More particularly, at the end of the step of FIG. 3E, chip IR comprises substrate SUB2, interconnect structure BEOL2 coating the front side 100 of substrate SB2, insulating layer 300 resting on, and preferably in contact with, the back side 102 of substrate SUB2, via 200 comprising conductive core 201 laterally covered with insulating sheath 202. Via 200 crosses substrate SUB2 from its surface 100, and at least the sheath 202 of via 200 crosses layer 300 and is flush with a first surface of layer 300 opposite to a second surface of layer 300 which is in contact with substrate SUB2. Chip IR further comprises electrode 104 which rests on top of and in contact with core 201 on the side of surface 102 of substrate SUB2.

The method described in relation with FIGS. 3A-3E enables, during the forming of electrode 104, for the contact between electrode 104 and connection 112 (or core 201) to be performed in self-aligned fashion.

Further, the method described in relation with FIGS. 3A-3E enables, at the end of the forming of electrode 104, for the electrode 104 to be electrically insulated from substrate SUB2 by sheath 202 and by layer 300, substrate SUB2 being further electrically insulated from connection 112 by sheath 202. For example, sheath 202 extends upwards from surface 100 of substrate SUB2 to the surface of layer 300 which is opposite to the surface of layer 300 in contact with substrate SUB2.

An advantage of the method described in relation with FIGS. 3A-3E is that the mask alignment constraints, for example, to define electrode 104 in the conductive layer, are released with respect to the alignment constraints for the etch mask described in relation with FIG. 2B. Indeed, in the method described in relation with FIGS. 3A-3E, the alignment constraints are released due to the selectivity of the etching of FIG. 3A, to the deposition of layer 300 of FIG. 3B, to the CMP step of FIG. 3C, and to the selectivity of the etching of FIG. 3D when the latter is implemented.

As an example, in a plane parallel to surfaces 100 and 102, the largest dimension of core 201, for example, its diameter when via 200 has a disk-shaped cross-section, is in the range from 0.5 µm to 2 µm.

As an example, the thickness of sheath 202, for example, measured in a plane parallel to surfaces 100 and 102, is in the range from 50 nm to 300 nm.

As an example, at the end of the step of FIG. 3E, the thickness of substrate SUB2, for example measured orthogonally to its surfaces 100 and 102, is in the range from 200 nm to a few micrometers.

The implementation of the method described in relation with FIGS. 3A-3E to form the connection 112 and the electrode 104 of the chip IR described in relation with FIG. 1 enables to ensure the electric insulation between electrode 104 and substrate SUB2, which is not the case with the method example described in relation with FIGS. 2A-2C.

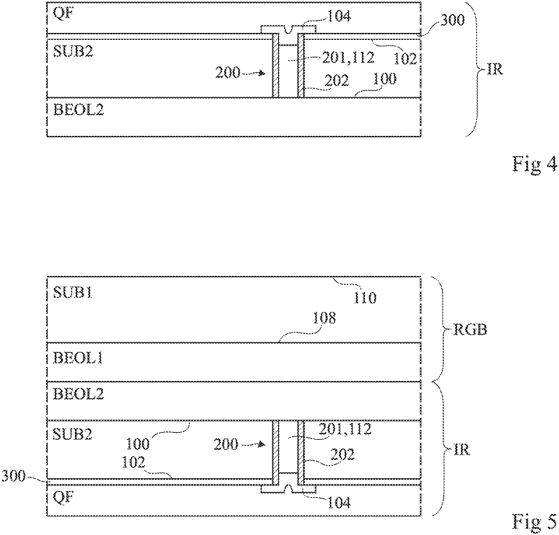

FIG. 4 shows, in a cross-section view, a step of a method of forming the device 1 of FIG. 1 according to an embodiment. More particularly, FIG. 4 illustrates a step of forming of a quantum film QF on the layer 300 and the electrode 104 of the structure obtained at the end of the method described in relation with FIG. 3. The forming of quantum film QF is within the abilities of those skilled in the art.

According to an embodiment, film QF is formed by one or a plurality of deposition steps, preferably over the entire plate, on the side of surface 102 of the substrate.

According to an embodiment, film QF is formed on top of and in contact with layer 300 and electrode 104. In an alternative embodiment, one or a plurality of conductive layers may be formed on layer 300 and electrode 104, for example, during one or a plurality of steps of continuous deposition, and the QF film is then formed on top of and in contact with the last conductive layer formed.

As an example, the thickness of quantum film QF is in the range from 400 nm to 800 nm.

According to an embodiment, film QF is configured to convert infrared light into electron-hole pairs, for example when chip IR is intended to form part of the device 1 of FIG. 1.

According to an embodiment, when chip IR is intended to form part of the device 1 of FIG. 1, electrode 104 is made of a material transparent to infrared radiation, for example, of zinc oxide and/or of indium-tin oxide.

In alternative embodiments, not illustrated, chip IR may not be assembled to chip RGB.

In such variants, chip IR may be intended to receive light on the side of surface 102 of substrate SUB2, and film QF may then be configured to convert light other than infrared light into electron-hole pairs. When chip IR is intended to receive light on the side of surface 102 of substrate SUB2, the electrode may not be transparent to the light received by chip IR, or, at least, to the wavelengths of the light that film QF converts into electron-hole pairs.

FIG. 5 shows, in a cross-section view, another step of a method of manufacturing the device 1 of FIG. 1 according to an embodiment. More particularly, FIG. 5 illustrates a step of assembly of the chip IR obtained after the implementation of the step of FIG. 4, with chip RGB.

Thus, at the step of FIG. 5, chip RGB comprising substrate SUB1 having its surface 108 coated with structure BEOL1 and having its surface 110 intended to receive light 106 (FIG. 1) is provided.

At the step of FIG. 5, chip RGB is mounted on, or assembled with, chip IR. More particularly, at the step of FIG. 5, structure BEOL1 is mounted on, or assembled with, structure BEOL2. As an example, structure BEOL1 is assembled with structure BEOL2 by molecular bonding. The implementation of this assembly step is within the abilities of those skilled in the art.

Although this is not illustrated in FIG. 5, additional steps may be provided, for example to form on the exposed surface 110 of substrate SUB 1 one or a plurality of passivation layers and/or one or a plurality of antireflection coatings and/or one or a plurality of filters and/or one or a plurality of lenses.

According to an embodiment, device 1 is a light sensor, for example, configured to deliver an image of a scene. For example, the substrate SUB1 of chip RGB comprises a plurality of photodetector elements enabling to acquire a two-dimensional color or black-and-white image of a scene, and chip IR comprises a plurality of depth pixels, each configured to deliver depth information relative to the scene, chip IR for example enabling to acquire a depth map of the scene. For example, device 1 is a light sensor configured to implement a face recognition.

Embodiments and variants of a method comprising the manufacturing of the connection 112 and of the electrode 104 of chip IR, the forming of the film QF of chip IR, and the assembly of chip IR to chip RGB have been previously described. As previously indicated, chip IR may not be assembled to chip RGB, that is, not form part of the device 1 of FIG. 1 and, in this case, the step of FIG. 5 may be omitted. Further, in the described embodiments and variants, chip IR comprises film QF. In alternative embodiments not illustrated, chip IR does not comprise film QF, for example when chip IR is not an infrared sensor, and the step of FIG. 4 is omitted. Electrode 104 and connection 112 then enable, for example, to electrically connect the structure BEOL2 of chip IR to an electric conductor external to chip IR.

Various embodiments and variants have been described. Those skilled in the art will understand that certain features of these various embodiments and variants may be combined, and other variants will occur to those skilled in the art. In particular, the steps described to form an electrode 104 in contact with the core 201 of a via 200 may be implemented simultaneously for a plurality of vias 200, so that the core 201 of each of these vias 200 is in contact with an electrode 104.

Finally, the practical implementation of the described embodiments and variations is within the abilities of those skilled in the art based on the functional indications given hereabove.

Manufacturing method may be summarized as including the steps of providing a silicon substrate (SUB2) having a front surface (100) coated with an interconnect structure (BEOL2), a rear surface (102) opposite to the front surface (100), at least one via (200) vertically penetrating into the substrate (SUB2) from the front surface (100) across a portion of the thickness of the substrate (SUB2), said at least one via (200) comprising a silicon conductive core (201) and a silicon oxide insulating sheath (202) capable of including silicon nitride, the sheath (202) covering the core (201) and electrically insulating it from the substrate (SUB2); etching, from the rear surface (102), the substrate (SUB2) selectively over the sheath (202) so that a portion of said at least one via (200) protrudes from the rear surface (102); depositing a silicon oxide insulating layer (300) capable of including silicon nitride on the side of the rear surface (102) across a thickness greater than a height of the protruding portion of said at least one via (200); performing a chemical-mechanical polishing of the insulating layer (300) to expose the conductive core (201) of said at least one via while leaving in place a portion of the thickness of the insulating layer (300) on the rear surface (102); and forming a conductive electrode (104) on the rear surface (102) and in contact with the core (201) of said at least one via (200).

The step of forming of the electrode (104) may include the deposition of a conductive layer on the insulating layer (300) and in contact with the core (201) of said at least one via (200), and a step of removal of a portion of the conductive layer while leaving in place said electrode (104).

The insulating layer (300) may be deposited on top of and in contact with the rear surface (102) of the substrate (SUB2) and the protruding portion of said at least one via (200).

The method may further include, between the polishing step and the step of forming of the electrode (104), a step of etching of a portion of the core (201) of said at least one via (200), the etching being implemented on the side of the rear surface (102) and being selective over the sheath (202) and over the insulating layer (300).

The method may further include, after the step of forming of the electrode (104), a step of forming of a quantum film (QF) resting on the insulating layer (300) and the electrode (104).

The method may further include a step of provision of an additional silicon substrate (SUB1) having a front surface (108) coated with an additional interconnect structure (BEOL1) and a rear surface (110) opposite to the front surface (108) of the additional substrate (SUB 1) and intended to receive light (106); and a step of assembly of the interconnect structure (BEOL2) on the additional interconnect structure (BEOL1).

The quantum film (QF) may be configured to convert infrared light into electron-hole pairs and the electrode (104) may be made of a material transparent to infrared light, for example of zinc oxide and/or indium tin oxide.

The sheath (202) of said at least one via may be in contact with the core (201) of said at least one via.

Device (1) may be summarized as including a silicon semiconductor substrate (SUB2) including a front surface (100) and a rear surface (102) opposite to the front surface (100); an interconnect structure (BEOL2) coating the front surface (100); a silicon oxide insulating layer (300) capable of including silicon nitride, the insulating layer (300) resting on the rear surface (102); at least one via (200) including a silicon conductive core (201) laterally covered with a silicon oxide insulating sheath (202) capable of including silicon nitride, said at least one via (200) crossing the substrate (SUB2) from its front surface (100), at least the sheath (202) of said at least one via (200) crossing the insulating layer (300) and being flush with a first surface of the insulating layer (300) opposite to a second surface of the insulating layer (300) facing the substrate (SUB2); and a conductive electrode (104) resting on top of and in contact with the conductive core (201) of said at least one via, on the rear surface (102) of the substrate (SUB2).

The device (1) may further include a quantum film (QF) resting on the insulating layer (300) and the electrode (104).

The device (1) may further include an additional silicon substrate (SUB1) and an additional interconnect structure (BEOL1) resting on a front surface (108) of the additional substrate (SUB1), the interconnect structure (BEOL2) being assembled on the additional interconnect structure (BEOL1) and the additional substrate (SUB1) including a rear surface (110) opposite to its front surface (108) and intended to receive light (106).

The quantum film (QF) may be configured to convert infrared light into electron-hole pairs and the electrode (104) may be made of a material transparent to infrared light, for example of zinc oxide and/or of indium tin oxide.

The sheath (202) of said at least one via may be in contact with the core (201) of said at least one via.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
etching a silicon substrate having a front surface coated with an interconnect structure, a rear surface opposite to the front surface, and a first via extending into the substrate along a first direction that is transverse to the front surface, the first via comprising a silicon conductive core and a silicon oxide insulating sheath covering the core and electrically insulating the core from the substrate, the etching the substrate including etching from the rear surface selectively over the sheath so that a portion of the first via protrudes from the rear surface, the portion having a first height along the first direction;
depositing a silicon oxide insulating layer on the rear surface, the insulating layer having a first thickness along the first direction greater than the first height of the protruding portion of the first via ;
polishing the insulating layer to expose the conductive core of the first via, leaving a second thickness of the insulating layer on the rear surface; and
forming a conductive electrode on the rear surface and in contact with the core of the first via.

2. The method according to claim 1, wherein the forming of the electrode comprises depositing a conductive layer on the insulating layer and in contact with the core of the first via, and removing a portion of the conductive layer.

3. The method according to claim 1, wherein the insulating layer is deposited on the rear surface of the substrate and the protruding portion of the first via.

4. The method according to claim 1, further comprising, between the polishing and the forming of the electrode, an etching of a portion of the core of the first via, the etching being implemented on the side of the rear surface and being selective over the sheath and over the insulating layer.

5. The method according to claim 1, further comprising, after the forming of the electrode, a forming of a quantum film on the insulating layer and the electrode.

6. The method according to claim 5, further comprising:
forming an additional silicon substrate having a front surface coated with an additional interconnect structure and a rear surface opposite to the front surface of the additional substrate, the rear surface intended to receive light; and
forming the interconnect structure on the additional interconnect structure.

7. The method according to claim 5, wherein the quantum film is converts infrared light into electron-hole pairs and the electrode comprises a material transparent to infrared light.

8. The method according to claim 1, wherein the sheath of the first via is in contact with the core of the first via.

9. A device comprising:
a semiconductor substrate comprising a front surface and a rear surface opposite to the front surface;
an interconnect structure coating the front surface;
an insulating layer on the rear surface;
a first via comprising a conductive core laterally covered with an insulating sheath, the first via extending into the substrate along a first direction that is transverse to the front surface, the sheath of the first via extending through the insulating layer and being coplanar with a first surface of the insulating layer opposite to a second surface of the insulating layer, the second surface of the insulating layer being in contact with the substrate; and
a conductive electrode in contact with the rear surface of the substrate and the conductive core of the first via.

10. The device according to claim 9, further comprising a quantum film on the insulating layer and the electrode.

11. The device according to claim 10, further comprising an additional silicon substrate and an additional interconnect structure on a front surface of the additional substrate, the interconnect structure being in contact with the additional interconnect structure, the additional substrate comprising a rear surface that receives light opposite to its front surface.

12. The device according to claim 10, wherein the quantum film converts infrared light into electron-hole pairs and the electrode comprises a material transparent to infrared light.

13. The device according to claim 9, wherein the sheath of the first via is in contact with the core of the first via.

14. The device according to claim 9, wherein the insulating layer comprises silicon oxide and silicon nitride.

15. The device according to claim 9, wherein the insulating sheath comprises silicon oxide and silicon nitride.

16. A device comprising:
a substrate including a front surface and a rear surface opposite to the front surface, the substrate having a first thickness;
an interconnect structure on the front surface;
an insulating layer having a first surface on the rear surface and a second surface opposite the first surface;
a first via extending from the front surface to the second surface of the insulating layer along a first direction, the first direction being transverse to the front surface, the first via including:
a conductive core comprising a first sidewall that is transverse to the front surface and a first surface coplanar with the front surface, the conductive core having a first length along the first direction that is smaller than the first thickness;
an insulating sheath covering the first sidewall and extending along the first direction from the front surface to the second surface of the insulating layer, the insulating sheath being coplanar with the second surface of the insulating layer; and
a conductive electrode in contact with the rear surface of the substrate and the conductive core of the first via.

17. The device according to claim 16, wherein the conductive electrode comprises:
a first portion in contact with the conductive core, the first portion having a first sidewall that is coplanar with the first sidewall of the conductive core; and
a second portion that is in contact with the insulating layer.

18. The device according to claim 17, wherein the conductive core has a first width along a second direction transverse to the first direction and the second portion of the conductive electrode has a second width along the second direction that is greater than the first width.

19. The device according to claim 16, wherein the interconnect structure comprises a plurality of conductive layers and a plurality of insulating layers.

20. The device according to claim 16, wherein the interconnect structure comprises a plurality of antireflection layers.
